(19) United States
(12) Patent Application Publication
(10) Pub. No.: US 2021/0216009 A1
(43) Pub. Date: Jul. 15, 2021

(54) METHOD FOR PREPARING OPTICAL METASURFACES

(71) Applicant: SOUTH UNIVERSITY OF SCIENCE AND TECHNOLOGY OF CHINA, Shenzhen GD (CN)

(72) Inventors: Xing Cheng, Shenzhen (CN); Guixin Li, Shenzhen (CN); Xin Zhuang, Shenzhen (CN); Junhong Deng, Shenzhen (CN)

(73) Assignee: SOUTH UNIVERSITY OF SCIENCE AND UNIVERSITY OF CHINA, Shenzhen (CN)

(21) Appl. No.: 15/999,759

(22) PCT Filed: Dec. 7, 2017
(86) PCT No.: PCT/CN2017/115096

§ 371 Date: Aug. 20, 2018

(30) Foreign Application Priority Data
Sep. 20, 2017 (CN) 201710854313.7

(51) Int. Cl. G03F 1/78; G03F 7/033; G03F 1/60

(52) U.S. Cl. CPC G03F 1/78; G03F 1/60; G03F 7/033

(57) ABSTRACT

The present application discloses a method for preparing optical metasurfaces, wherein the method is performed based on nano-imprinting, and the template used in the method is an imprinting template with patterns of meta-atoms. The method for preparing optical metasurfaces provided by the present application can replace the electron beam lithography method used in fabricating meta-atoms, greatly reducing the costs, and greatly reducing the production time. The method provided by the present application significantly improves the production cost and the production time, achieving a low-cost, large-scale fabrication of metasurface-based optical elements within a short time, and having good industrialization prospects.

### TECHNICAL FIELD

The present application relates to the field of micro-nano processing, in particular, relates to the preparation of optical metasurfaces.

### BACKGROUND

Optical metamaterials are optical structural materials designed and constructed artificially in which the meta-atoms allow light to propagate in a way that is impossible for natural materials. The linear optical parameters of the metamaterials, such as effective dielectric constant, magnetic permeability, refractive index, etc., can be designed by regulating the constituent materials and geometry of the meta-atoms. In this way, the electromagnetic response of the meta-atoms is no longer limited to its own chemical composition. Some unique optical physical phenomena, such as negative refraction, super-resolution imaging and optical stealth etc., can be achieved through a rational design of optical metamaterials. However, the challenges encountered in nano-processing of three-dimensional metamaterials and their huge optical losses limit its practical application in the field of optics. The emergence of optical metasurfaces has solved the difficulties encountered with three-dimensional metamaterials. Metasurfaces are interfaces composed of a class of meta-atoms with spatially varying patterns. The metasurfaces are based on the concept that light undergoes a phase transformation when passing through a designed interface. The polarization, amplitude and phase of light can be effectively controlled at the sub-wavelength scale by introducing meta-atoms on substrates composed of metal and dielectric materials. The two-dimensional properties of the metasurfaces make it possible to achieve a preparation of optical elements which are more compact in volume and have lower-loss. In addition, the preparation process of ultra-thin metasurfaces is compatible with the existing complementary metal oxide semiconductor technology and is more easily integrated into the existing photoelectric technologies. To a certain extent, the emergence of metaplanes indicates the arrival of a new era of “plane optics”. The high-efficiency optical holographic imaging, lenses with high numerical apertures, and various planar diffractive optical elements, etc., can be achieved by using the metasurfaces.

At present, electron beam lithography technology is mainly used in the fabrication of meta-atoms of the metasurface-based optical elements that operates at wavelengths of visible and near-infrared bands. Limited by the small beam of the electron beam and the electron beam photoresist requires a certain amount of exposure to effectively transfer patterns, a long exposure time is required to inscribe an optical metasurface with small area, in addition, the electron beam lithography machines are extremely expensive. The industrialization of metasurface-based optical elements has been greatly limited by high manufacturing time costs and high instrument costs.

Therefore, the development of a more efficient and cheaper method for preparing optical metasurfaces has great significance for the development of this field.

### SUMMARY OF THE INVENTION

The present application provides a method for preparing optical metasurfaces, which can solve the problems of long preparation time and high costs in the prior art.

In order to achieve this purpose, the present application adopts the following technical solutions:

The present application provides a method for preparing optical metasurfaces, wherein the method is performed based on nano-imprinting, and the template used in the method is an imprinting template with patterns of meta-atoms.

In the present application, by applying nano-imprinting method to the preparation of optical metasurfaces, the electron beam lithography method used in conventional preparation of meta-atoms can be replaced, a low-cost, large-scale fabrication of metasurface-based optical elements can be achieved in a short time, and continuous submicron-scale patterning can be achieved on a flexible substrate in a roll-to-roll manner, achieving a large-scale production of high-precision optical metasurfaces. It is a breakthrough improvement compared to conventional electron beam lithography methods.

The followings are preferred technical solutions of the present application, but are not limitations to the technical solutions provided by the present application. The technical purpose and beneficial effects of the present application can be achieved and realized preferably through the following preferred technical solutions.

As a preferred technical solution of the present application, firstly, the meta functional patterns of the imprinting template with patterns of meta-atoms are transferred onto a nano-imprinting resist, and then post-processing is performed to obtain an optical metasurface, and the imprinting template with patterns of meta-atoms is any one of a polymer film imprinting template or a metal imprinting template.

Preferably, the imprinting template with patterns of meta-atoms is prepared by the following method:

(1) coating a layer of electron beam photoresist on a substrate, inscribing patterns of metasurface-atoms on the electron beam photoresist, and developing with a developer solution to obtain an electron beam photoresist mask, using the electron beam photoresist mask to etch the substrate, and removing the electron beam photoresist with a solvent to obtain a substrate with patterns of metasurface-atoms;
(2) transferring the patterns on the substrate with patterns of metasurface-atoms in step (1) onto a polymer film or a metal layer;
(3) lifting off the polymer film or metal layer from the substrate to obtain a polymer film imprinting template or a metal imprinting template.

In the preparation method of an imprinting template with patterns of meta-atoms described above, the patterns of metasurface-atoms on the substrate with patterns of metasurface-atoms are recessed nanoscale polyhedrons; after the patterns are transferred onto the polymer film imprinting template or the metal imprinting template, the patterns of metasurface-atoms on the polymer film imprinting template or the metal imprinting template are raised nanoscale polyhedrons.

As a preferred technical solution of the present application, during the preparation of the imprinting template with patterns of meta-atoms, when transferring the patterns on the substrate with patterns of metasurface-atoms onto the polymer film, the specific method of step (2) is: transferring the patterns on the substrate with patterns of metasurface-atoms onto the polymer film by using a nano-imprinting method.

As a preferred technical solution of the present application, during the preparation of the imprinting template with patterns of meta-atoms, when transferring the pattern on the substrate with patterns of metasurface-atoms onto the metal layer, the specific method of step (2) is: firstly, evaporating a layer of metal film on an etched silicon substrate by using an electron beam evaporation method, and then growing a metal layer by an electroplating method.

In the present application, according to different materials of the imprinting template, a suitable preparation method is preferred, which is benefit to the optimization of production processes and the saving of production costs.

As a preferred technical solution of the present application, during the preparation of the imprinting template with patterns of meta-atoms, the substrate in step (1) includes silicon wafer or quartz.

Preferably, the coating in step (1) is spin-coating.

Preferably, the electron beam photoresist in step (1) is an electron beam positive photoresist.

Preferably, in step (1), the method for inscribing patterns of metasurface-atoms on the electron beam photoresist is electron beam lithography.

Preferably, the electron beam photoresist in step (1) has a coating thickness of 150 nm to 400 nm, preferably 150 nm. Specific thickness can be determined depending on the selection ratio of the selected electron beam photoresist to the silicon wafer during inductively coupled plasma etching.

Preferably, in step (1), the method for etching the substrate is inductively couple plasma (ICP) etching.

Preferably, in step (1), the depth for etching the substrate is in the range of 150 nm to 400 nm, preferably 200 nm. Specific thickness is related to the success rate of the subsequent fabrication of nickel template, the success rate of using the nickel template to perform nano-imprinting for patterns of metasurface-atoms, and the success rate of lifting off the metal evaporated on the nano-imprinting resist, which can be adjusted according to requirements.

As a preferred technical solution of the present application, the method for transferring the meta functional patterns of the imprinting template with patterns of meta-atoms onto a nano-imprinting resist is: heating the nano-imprinting resist to make it soft, pressurizing the softened nano-imprinting resist so that the patterns on the imprinting template can be printed onto the nano-imprinting resist, reducing temperature to cure the nano-imprinting resist, removing the pressure, separating the imprinting template from the nano-imprinting resist, cleaning residual resist to obtain a nano-imprinting resist with meta-patterns.

Preferably, the heating temperature is in the range of 40° C. to 60° C., preferably 50° C. higher than the glass transition temperature of the nano-imprinting resist.

Preferably, the pressure for pressurization is in the range of 4 MPa to 6 MPa, preferably 5 MPa.

Preferably, the temperature is reduced to a temperature of 20° C. to 30° C., preferably 25° C.

Preferably, the method for cleaning residual resist is reactive ion etching (RIE).

As a preferred technical solution of the present application, if the nano-imprinting resist is coated on a dielectric layer, the post-processing method for preparing an optical metasurface is:

evaporating metal on the nano-imprinting resist with meta-patterns, dissolving the nano-imprinting resist with a solvent, lifting off the metal evaporated on the nano-imprinting resist to obtain an optical metasurface.

Preferably, the evaporation is electron beam evaporation.

Preferably, the evaporated metal has a thickness of 20 nm to 70 nm, preferably 30 nm.

As a preferred technical solution of the present application, the dielectric layer is evaporated on a metal reflective layer, and the metal reflective layer is evaporated on a substrate.

Preferably, the evaporation is electron beam evaporation.

Preferably, the substrate includes any one of silicon wafer, quartz or a flexible material.

Preferably, the flexible material is polyethylene glycol terephthalate (PET).

As a preferred technical solution of the present application, if the nano-imprinting resist is coated on a transparent substrate, the post-processing method for preparing an optical metasurface is:

using a nano-imprinting resist as a mask, etching the transparent substrate, evaporating a metal layer on the nano-imprinting resist with meta-patterns and the grooves etched on the transparent substrate, dissolving the nano-imprinting resist with a solvent, lifting off the metal evaporated on the nano-imprinting resist to obtain an optical metasurface.

Preferably, the depth for etching the transparent substrate is the thickness of the metal layer of the metasurface-atoms.

Preferably, the evaporation is electron beam evaporation.

Preferably, the evaporated metal has a thickness of 20 nm to 70 nm, preferably 30 nm.

As a preferred technical solution of the present application, a dielectric layer is evaporated on the side on which the transparent substrate is etched, a metal reflective layer is evaporated on the dielectric layer, and the metal reflective layer and a base are bonded.

Preferably, the evaporation is electron beam evaporation.

Preferably, the base includes silicon wafer or quartz.

As a preferred technical solution of the present application, the material of the polymer film is any one selected from the group consisting of polycarbonate (PC), polymethyl methacrylate (PMMA), poly-ether-ether-ketone (PEEK), polyimide (PI), polyethylene glycol terephthalate (PET), polyurethane (PU), polytetrafluoroethylene (PTFE), polyvinylidene fluoride (PVDF), polydimethylsiloxane (PDMS), and a combination of at least two thereof. Typical but non-limiting combinations are: the combination of PC and PMMA, the combination of PEEK and PI, the combination of PET and PU, the combination of PTFE, PVDF, and PDMS, etc.

As a preferred technical solution of the present application, the material of the metal imprinting template is Ni. Ni used as a template does not crush during the imprinting process and is suitable for roll-to-roll nano-imprinting commonly used in industrial production.

In the present application, one of the above two types of nano-imprinting post-processing methods can be selected according to the actual requirements of the metasurface-based optical elements so as to adapt to the production requirements of the metasurface-based optical elements and make a flexible choice between forward preparation and reverse preparation of metasurface-based optical elements. In the present application, regardless of which of the above two types of nano-imprinting post-treatment methods is used, the evaporated metal which has not been lifted off is used as the metal film constituting the metasurface-atoms.

As a preferred technical solution of the present application, the nano-imprinting method includes any one of thermoplastic nano-imprinting, ultraviolet curing nano-imprinting, roll-to-roll nano-imprinting or roll-to-plate nano-imprinting.

Compared with the prior art, the present application has the following beneficial effects:

The method for preparing optical metasurfaces provided by the present application can replace the electron beam lithography method used in fabricating meta-atoms, greatly reducing the costs, and greatly reducing the production time. The method provided by the present application is suitable for industrial production. When the same pattern of meta-atoms is subjected to a large number of repetitive inscriptions, the electron beam lithography method needs to inscribe the pattern one by one, and the electron beam lithography needs to be used for a long time. However, the electron beam lithography is used for only one time to fabricate the nickel template in the method provided by the present application, in which nano-imprinting is used to inscribe the same pattern on large-scale repeatedly. If a pattern with an area of 1 square centimeter is to be inscribed for 1 million times, the production cost of the method provided by the present application is approximately one-millionth of the cost when using electron beam lithography, and the production time is approximately 77-thousandth of the time required for electron beam lithography. The method provided by the present application significantly improves the production cost and the production time, achieving a low-cost, large-scale fabrication of metasurface-based optical elements within a short time, and having good industrialization prospects.

### DESCRIPTION OF THE DRAWINGS

FIG. 1.1 is a schematic view of the product obtained in step a of Example 1;

FIG. 1.2 is a schematic view of the product obtained in step b of Example 1;

FIG. 1.3 is a schematic view of the product obtained in step c of Example 1;

FIG. 1.4 is a schematic view of the product obtained in step d of Example 1;

FIG. 1.5 is a schematic view of the product obtained in step e of Example 1;

FIG. 1.6.1 is a schematic view of the product obtained in step f of Example 1;

FIG. 1.6.2 is a top view (schematic view) of the Ni metal imprinting template with raised patterns of metasurface-atoms of the product obtained in step f of Example 1;

FIG. 1.7 is a schematic view of the product obtained in step g of Example 1;

FIG. 1.8 is a schematic view of the product obtained in step h of Example 1;

FIG. 1.9 is a schematic view of the product obtained in step i of Example 1;

FIG. 1.10 is a schematic view of the product obtained in step j of Example 1;

FIG. 1.11 is a schematic view of the product obtained in step k of Example 1;

FIG. 2.1 is a schematic view of the product obtained in step a of Example 2;

FIG. 2.2 is a schematic view of the product obtained in step b of Example 2;

FIG. 2.3 is a schematic view of the product obtained in step c of Example 2;

FIG. 2.4 is a schematic view of the product obtained in step d of Example 2;

FIG. 2.5 is a schematic view of the product obtained in step e of Example 2;

FIG. 3.1 is a schematic view of the product obtained in step a of Example 3;

FIG. 3.2 is a schematic view of the product obtained in step b of Example 3;

FIG. 3.3 is a schematic view of the product obtained in step c of Example 3;

FIG. 3.4 is a schematic view of the product obtained in step d of Example 3;

FIG. 3.5 is a schematic view of the product obtained in step e of Example 3;

FIG. 3.6 is a schematic view of the product obtained in step f of Example 3; wherein 1—electron beam positive photoresist, 2—silicon wafer, 3—Ni metal imprinting template, 4—nano-imprinting resist, 5—dielectric layer constituting metasurface-based optical elements, 6—metal reflective layer constituting metasurface-based optical elements, 7—substrate, 8—metal film constituting metasurface-atoms, 9—silicon wafer with patterns of metasurface-atoms, 10—polymer film, 11—Ni metal imprinting template or polymer film imprinting template, 12—nano-imprinting resist having good adhesion with transparent substrate, 13—transparent substrate, 14—metal layer constituting metasurface-atoms, 15—base.

### DETAILED DESCRIPTION

The technical solutions of the present application will be further described below with reference to the accompanying drawings and through specific embodiments. However, the following embodiments are only simple examples of the present application, and do not represent or limit the protection scope of the present application. The protection scope of the present application is subject to the claims.

Example 1

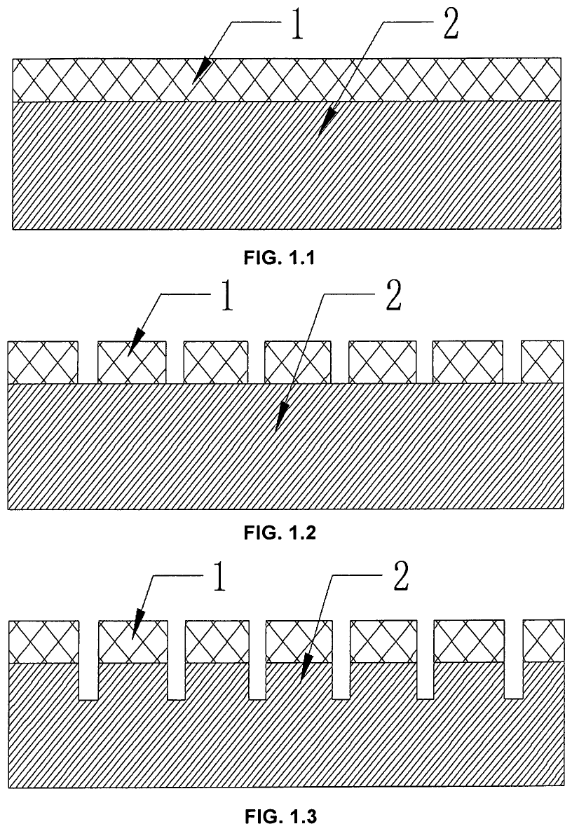

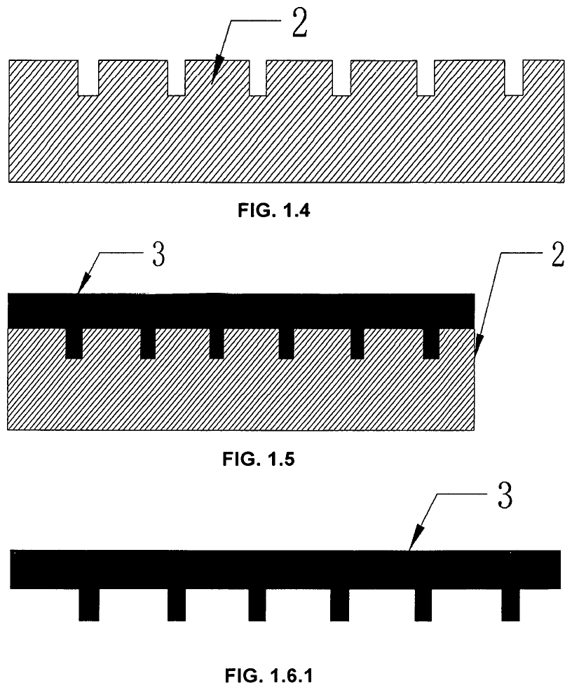

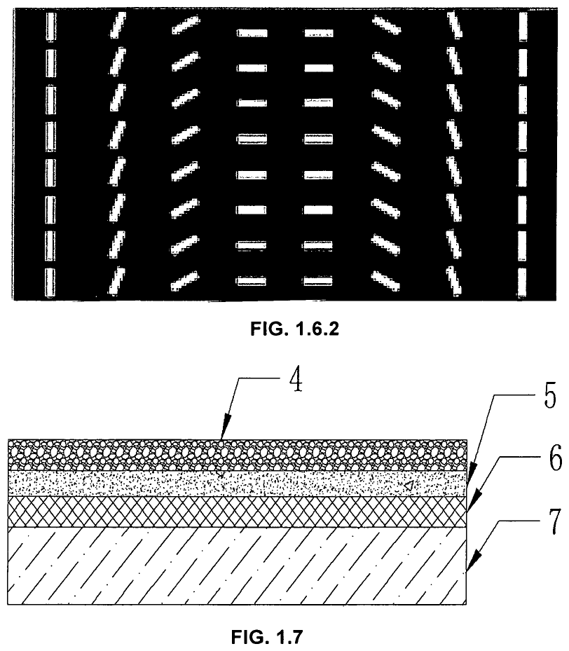

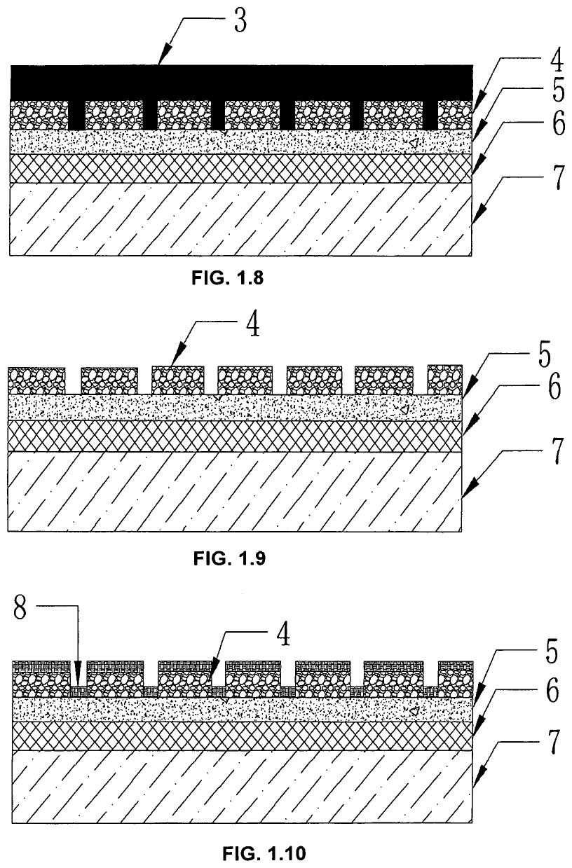

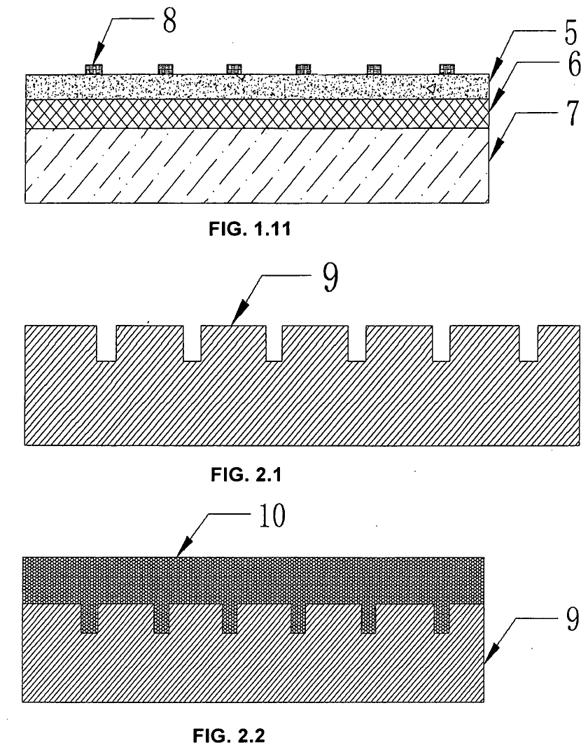

This example provides a method for preparing an optical metasurface-based optical element, which was performed based on nano-imprinting. The specific method is as follows:
a. a layer of electron beam positive photoresist 1 with a thickness of about 150 nm was spin-coated on a silicon wafer 2 (a schematic view of the product shown in FIG. 1.1);
b. designed patterns of metasurface-atoms were inscribed by using an electron beam lithography method, and developed with a developer solution (a schematic view of the product shown in FIG. 1.2);
c. the silicon wafer 2 was subjected to ICP etching by using the electron beam lithography positive resist 1 as a mask, with an etching depth of about 200 nm (a schematic view of the product shown in FIG. 1.3);
d. the electron beam positive photoresist 1 was removed by using a corresponding solvent (a schematic view of the product shown in FIG. 1.4);
e. a layer of Ni metal film was evaporated on the etched silicon wafer 2 by an electron beam evaporation technique, then a Ni metal layer was grown by using an electroplating method, this layer was Ni metal imprinting template 3 (a schematic view of the product shown in FIG. 1.5);
f. the electroplated Ni metal layer was lifted off from the silicon substrate to complete the preparation of the Ni metal imprinting template 3 (a schematic view of the product shown in FIG. 1.6.1). The Ni metal imprinting template 3 was provided with raised patterns of metasurface-atoms, and its top view is shown in FIG. 1.6.2;
g. a metal reflective layer constituting the metasurface-based optical element 6 and a dielectric layer constituting the metasurface-based optical element 5 were evaporated on a substrate 7 respectively (the substrate 7 can be a silicon substrate, a quartz substrate, or a flexible substrate such as PET) by an electron beam evaporation technique, and then a layer of nano-imprinting resist 4 was spin-coated (a schematic view of the product shown in FIG. 1.7);
h. the patterns on the Ni metal imprinting template 3 were transferred onto the nano-imprinting resist 4 by using a nano-imprinting technique. The specific method was: firstly, the temperature was heated to about 50° C. above the glass transition temperature of the polymer materials constituting the nano-imprinting resist 4, so that the nano-imprinting resist 4 was softened, a pressure of 5 MPa was applied, so that the patterns on the Ni metal imprinting template 3 were printed on the nano-imprinting resist 4. Then, the temperature was reduced to 25° C. so that the nano-imprinting resist 4 was cured. After the pressure was removed, patterns complementary to the Ni metal imprinting template 3 were transferred to the nano-imprinting resist 4 (a schematic view of the product shown in FIG. 1.8);
i. the Ni metal imprinting template 3 was separated from the nano-imprinting resist 4 and residual resist was cleaned by a RIE etching technique (a schematic view of the product shown in FIG. 1.9);
j. a metal film constituting the metasurface-based optical element 8 with a corresponding thickness was evaporated by using an electron beam evaporation method (a schematic view of the product shown in FIG. 1.10);
k. the nano-imprinting resist was dissolved with a corresponding solvent and the corresponding metal was lifted off to obtain a metasurface-based optical element (a schematic view of the product shown in FIG. 1.11).

According to the preparation process of this example, if PET is used as a substrate, the production cost for repeatedly fabricating metasurface-based optical elements with an area of a single pattern of metasurface-atoms of one square centimeter and a total area of one hundred square meters is 10,000-yuan (CNY), and the production time is 130 hours.

### Example 2

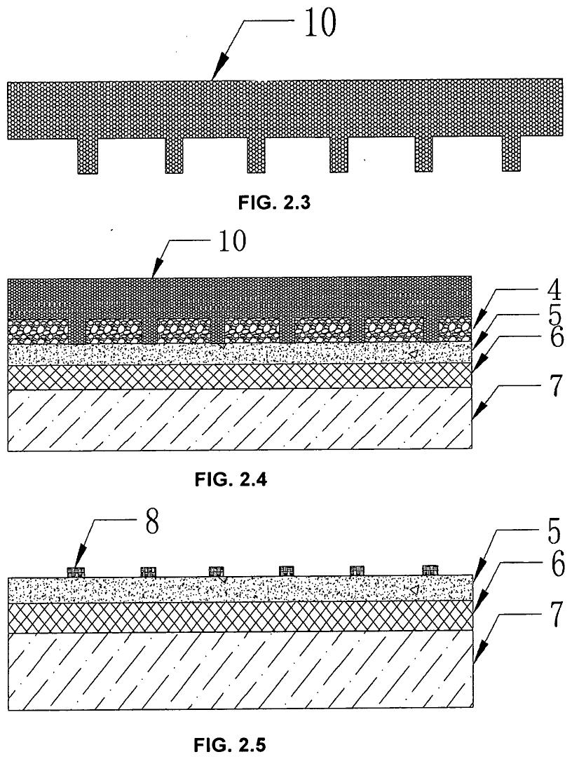

This example provides a method for preparing an optical metasurface-based optical element, which was performed based on nano-imprinting. The specific method is as follows:
a. A silicon wafer with designed patterns of metasurface-atoms 9 was prepared referring to the four steps a, b, c, and d of Example 1 (a schematic view of the product shown in FIG. 2.1).
b. the patterns on the silicon wafer with designed patterns of metasurface-atoms 9 were transferred onto a polymer film 10 (such as PC, PMMA, PEEK, PI, PET, PU, PTFE, PVDF, or PDMS, etc.) by using a nano-imprinting method (a schematic view of the product shown in FIG. 2.2);
c. the polymer film 10 was separated from the silicon wafer 9, and the patterns on the silicon wafer 9 were transferred onto the polymer film 10 to complete the fabrication of a nano-imprinting template (a schematic view of the product shown in FIG. 2.3);
d. a metal reflective layer constituting the metasurface-based optical element 6 and a dielectric layer constituting the metasurface-based optical element 5 were evaporated on a substrate 7 respectively (the substrate 7 can be silicon substrate, a quartz substrate, or a flexible substrate such as PET) by an electron beam evaporation technique, and then a layer of nano-imprinting resist 4 was spin-coated. The nano-imprinting resist 4 was imprinted with the polymer film 10 with patterns of metasurface-atoms to transfer the patterns on the film onto the nano-imprinting resist 4 (a schematic view of the product shown in FIG. 2.4). Specific process for transferring was referred to step h of Example 1;
e. the polymer film 10 was separated from the nano-imprinting resist 4 and residual resist was cleaned by a RIE etching technique. Metal was evaporated and the nano-imprinting resist 4 was dissolved with a corresponding solvent. The corresponding metal was lifted off to obtain a metasurface-based optical element (a schematic view of the product shown in FIG. 1.11). Specific methods were referred to steps i, j and k of Example 1.

According to the preparation process of this example, if PET is used as a substrate, the production cost for repeatedly fabricating metasurface-based optical elements with an area of a single pattern of metasurface-atoms of one square centimeter and a total area of one hundred square meters is 10,000-yuan (CNY), and the production time is 130 hours.

### Example 3

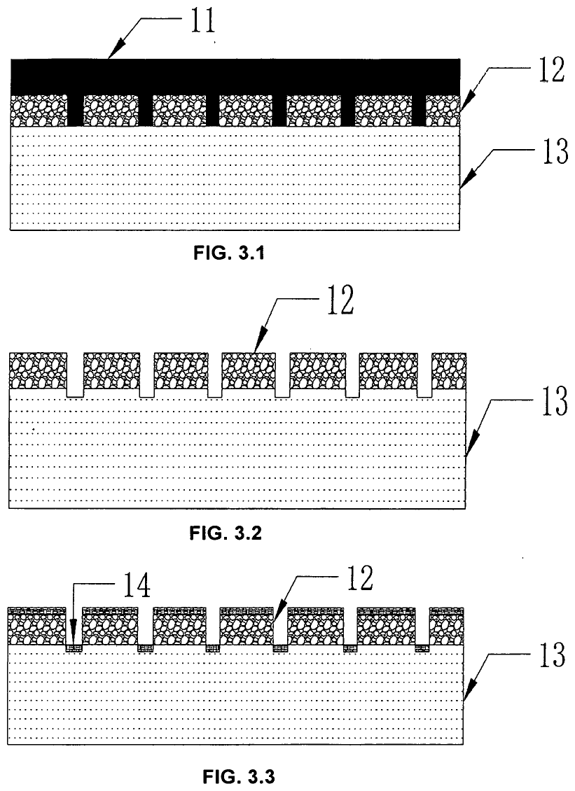

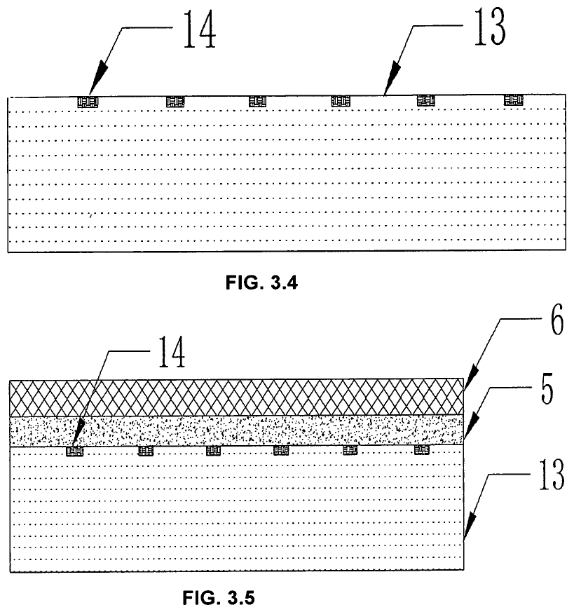

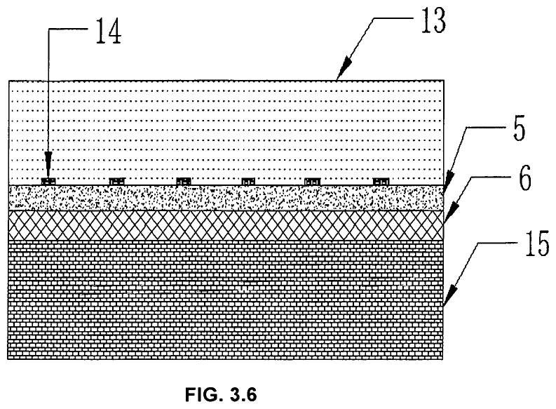

This example provides a method for preparing an optical metasurface-based optical element, which was performed based on nano-imprinting. The specific method is as follows:
a. a nano-imprinting resist having good adhesion with transparent substrate 12 was spin-coated on a transparent substrate 13. The nano-imprinting resist 12 was imprinted with the fabricated Ni metal imprinting template or polymer film imprinting template 11 with designed patterns of metasurface-atoms to transfer the patterns onto the nano-imprinting resist 12 (a schematic view of the product shown in FIG. 3.1). Specific process for transferring and process for cleaning after transferring were referred to steps h and i of Example 1;
b. the nano-imprinting resist 12 was used as a mask to etch the transparent substrate 13. The depth for etching was the thickness of the designed metal layer of the metasurface-atoms (a schematic view of the product shown in FIG. 3.2);
c. a metal layer constituting the metasurface-atoms 14 was evaporated on the nano-imprinting resist 12 by an electron beam evaporation technique (a schematic view of the product shown in FIG. 3.3);
d. the nano-imprinting resist 12 was dissolved with a corresponding solvent and the corresponding metal was lifted off (a schematic view of the product shown in FIG. 3.4);
e. a dielectric layer constituting the metasurface-based optical element 5 and a metal reflective layer constituting the metasurface-based optical element 6 was evaporated respectively by using an electron beam evaporation technique (a schematic view of the product shown in FIG. 3.5);
f. the metal reflective layer constituting the metasurface-based optical element 6 was bonded with a base 15 of silicon wafer or a quartz by using a bonding technique, so that a metasurface-based optical element was obtained by reverse preparation (a schematic view of the product shown in FIG. 3.6).

According to the preparation process of this example, the production cost for repeatedly fabricating metasurface-based optical elements with an area of a single pattern of metasurface-atoms of one square centimeter and a total area of one hundred square meters is 760,000-yuan (CNY), and the production time is 160 hours.

### Comparative Example 1

An electron beam lithography method was used in this comparative example to prepare the product. The specific process is as follows:

A metal layer and a dielectric layer constituting the metasurface-based optical element was respectively evaporated on a silicon/quartz/flexible substrate by using an electron beam evaporation technique. Then, a layer of electron beam positive photoresist with a thickness of about 150 nm was spin-coated. The patterns of meta-atoms were inscribed by using electron beam lithography technology, and developed with a corresponding developer solution. A metal with a corresponding thickness was evaporated by using an electron beam evaporation technique. The electron beam photoresist was dissolved with a corresponding solvent and the corresponding metal was lifted off to complete the fabrication of a metasurface-based optical element.

The same product as the metasurface-based optical element finally obtained in Example 1 was prepared.

When the same pattern is subjected to a large number of repetitive inscriptions, the electron beam lithography method needs to inscribe the pattern one by one, and the electron beam lithography needs to be used for a long time. According to the method of this comparative example, 1,000,000 times of inscriptions need to be carried out when fabricating metasurface-based optical elements with an area of a single pattern of metasurface-atoms of one square centimeter and a total area of one hundred square meters. Although the structure and performance of the product of this comparative example are the same as those of the metasurface-based optical element finally obtained in Example 1, the production cost of this comparative example is as high as approximately 10 billion CNY and the production time is as high as 10,000,000 hours.

As can be seen from the comprehensive of the above examples and comparative example, the method described in the present application uses nano-imprinting technology to replace the electron beam lithography, achieving a low-cost, large-scale fabrication of metasurface-based optical elements within a short time, and having good industrialization prospects.

The applicant states that the detailed technological equipment and technological processes of the present application are illustrated in the present application through the embodiments described above, however, the present application is not limited to the detailed technological equipment and technological processes described above, i.e. does not mean that the application must rely on the detailed technological equipment and technological processes described above to implement. It should be apparent to those skilled in the art that, for any improvement of the present application, the equivalent replacement

of the raw materials of the present application, the addition of auxiliary components and the selection of specific methods, etc., all fall within the protection scope and the disclosure scope of the present application.

What is claimed is:

1. A method for preparing optical metasurfaces, wherein the method is performed based on nano-imprinting, and the template used in the method is an imprinting template with patterns of meta-atoms.

2. The method according to claim 1, wherein firstly, the meta functional patterns of the imprinting template with patterns of meta-atoms are transferred onto a nano-imprinting resist, and then post-processing is performed to obtain an optical metasurface, and the imprinting template with patterns of meta-atoms is any one of a polymer film imprinting template or a metal imprinting template.

3. The method according to claim 1, wherein the imprinting template with patterns of meta-atoms is prepared by the following method:
(1) coating a layer of electron beam photoresist on a substrate, inscribing patterns of metasurface-atoms on the electron beam photoresist, and developing with a developer solution to obtain an electron beam photoresist mask, using the electron beam photoresist mask to etch the substrate, and removing the electron beam photoresist with a solvent to obtain a substrate with patterns of metasurface-atoms;
(2) transferring the patterns on the substrate with patterns of metasurface-atoms in step (1) onto a polymer film or a metal layer;
(3) lifting off the polymer film or metal layer from the substrate to obtain a polymer film imprinting template or a metal imprinting template.

4. The method according to claim 3, wherein during the preparation of the imprinting template with patterns of meta-atoms, when transferring the patterns on the substrate with patterns of metasurface-atoms onto the polymer film, the specific method of step (2) is: transferring the patterns on the substrate with patterns of metasurface-atoms onto the polymer film by using a nano-imprinting method.

5. The method according to claim 3, wherein during the preparation of the imprinting template with patterns of meta-atoms, when transferring the pattern on the substrate with patterns of metasurface-atoms onto the metal layer, the specific method of step (2) is: firstly, evaporating a layer of metal film on a substrate with patterns of metasurface-atoms by using an electron beam evaporation method, and then growing a metal layer by an electroplating method.

6. The method according to claim 3, wherein during the preparation of the imprinting template with patterns of meta-atoms, the substrate in step (1) includes silicon wafer or quartz;
the coating in step (1) is spin-coating;
the electron beam photoresist in step (1) is an electron beam positive photoresist;
in step (1), the method for inscribing patterns of metasurface-atoms on the electron beam photoresist is electron beam lithography;
the electron beam photoresist in step (1) has a coating thickness of 150 nm to 400 nm, preferably 150 nm;
in step (1), the method for etching the substrate is inductively couple plasma etching;
in step (1), the depth for etching the substrate is in the range of 150 nm to 400 nm.

7. The method according to claim 2, wherein the method for transferring the meta functional patterns of the imprinting template with patterns of meta-atoms onto a nano-imprinting resist is: heating the nano-imprinting resist to make it soft, pressurizing the softened nano-imprinting resist so that the patterns on the imprinting template can be printed onto the nano-imprinting resist, reducing temperature to cure the nano-imprinting resist, removing the pressure, separating the imprinting template from the nano-imprinting resist, cleaning residual resist to obtain a nano-imprinting resist with meta-patterns.

8. The method according to claim 7, wherein if the nano-imprinting resist is coated on a dielectric layer, the post-processing method for preparing an optical metasurface is:
evaporating metal on the nano-imprinting resist with meta-patterns, dissolving the nano-imprinting resist with a solvent, lifting off the metal evaporated on the nano-imprinting resist to obtain an optical metasurface.

9. The method according to claim 8, wherein the dielectric layer is evaporated on a metal reflective layer, and the metal reflective layer is evaporated on a substrate.

10. The method according to of claim 7, wherein if the nano-imprinting resist is coated on a transparent substrate, the post-processing method for preparing an optical metasurface is:
using a nano-imprinting resist as a mask, etching the transparent substrate, evaporating a metal layer on the nano-imprinting resist with meta-patterns and the grooves etched on the transparent substrate, dissolving the nano-imprinting resist with a solvent, lifting off the metal evaporated on the nano-imprinting resist to obtain an optical metasurface.

11. The method according to claim 10, wherein a dielectric layer is evaporated on the side on which the transparent substrate is etched, a metal reflective layer is evaporated on the dielectric layer, and the metal reflective layer and a base are bonded.

12. The method according to claim 2, wherein the material of the polymer film imprinting template is any one selected from the group consisting of polycarbonate PC, polymethyl methacrylate PMMA, poly-ether-ether-ketone PEEK, polyimide PI, polyethylene glycol terephthalate PET, polyurethane PU, polytetrafluoroethylene PTFE, polyvinylidene fluoride PVDF, polydimethylsiloxane PDMS, and a combination of at least two thereof.

13. The method according to claim 2, wherein the material of the metal imprinting template is Ni.

14. The method according to claim 1, wherein the nano-imprinting method includes any one of thermoplastic nano-imprinting, ultraviolet curing nano-imprinting, roll-to-roll nano-imprinting or roll-to-plate nano-imprinting.

15. The method according to claim 7, wherein the heating temperature is in the range of 40° C. to 60° C. higher than the glass transition temperature of the nano-imprinting resist;
the pressure for pressurization is in the range of 4 MPa to 6 MPa;
the temperature is reduced to a temperature of 20° C. to 30° C.;
the method for cleaning residual resist is reactive ion etching.

16. The method according to claim 8, wherein the evaporation is electron beam evaporation; the evaporated metal has a thickness of 20 nm to 70 nm.

17. The method according to claim 9, wherein the evaporation is electron beam evaporation; the substrate includes any one of silicon wafer, quartz or a flexible material.

18. The method according to claim 10, wherein the depth for etching the transparent substrate is the thickness of the metal layer of the metasurface-atoms;
the evaporation is electron beam evaporation;
the evaporated metal has a thickness of 20 nm to 70 nm.

19. The method according to claim 11, wherein the evaporation is electron beam evaporation; the base includes silicon wafer or quartz.
